(19) United States
(12) Patent Application Publication
(10) Pub. No.: US 2012/0049235 A1
(43) Pub. Date: Mar. 1, 2012

(54) Organic Light Emitting Diode Packaging Structure and Manufacturing Method Thereof

(75) Inventor: Yao-An Mo, Hsin-Chu (TW)

(73) Assignee: AU OPTRONICS CORPORATION, Hsin-Chu (TW)

(21) Appl. No.: 13/038,446

(22) Filed: Mar. 2, 2011

(30) Foreign Application Priority Data
Aug. 24, 2010 (TW) 099128233

(51) Int. Cl. H01L 51/56; H01L 51/52

(52) U.S. Cl. 257/99; 438/26; 257/E51.018

(57) ABSTRACT

An organic light emitting diode packaging structure and a manufacturing method thereof is provided. The organic light emitting diode packaging structure includes a substrate, an organic light emitting diode, a film, and a metal layer. The organic light emitting diode is disposed on the substrate. The film has a surface facing the substrate. The surface has a recess formed thereon. The metal layer is applied to the surface of the film, so that the metal layer forms an accommodating space in the recess to accommodate the organic light emitting diode. The present invention utilizes the metal layer to package the organic light emitting diode and therefore has the advantages of thinner in thickness and lighter in weight. As a result, the present invention can be applied to large organic light emitting diode products or portable electronic products.

### BACKGROUND OF THE INVENTION

1. Field of the Invention

The present invention generally relates to an organic light emitting diode (OLED) packaging structure and a manufacturing method thereof. More particularly, the present invention relates to a structure that utilizes a metal layer to encapsulate an organic light emitting diode and the packaging method thereof

2. Description of the Prior Art

An organic light emitting diode (OLED) is a type of light emitting diode structure formed from a composite of organic compounds and an emission layer. Products currently on the market that are pertinent to organic light emitting diodes include lighting fixtures, electronic billboards, television monitors, digital device displays, and other related electronic devices.

In comparison to the conventional light emitting diode (LED), an organic light emitting diode is lighter in weight, slimmer in size, more flexible in nature, softer in texture, has lower heat emission levels, and is capable of displaying many colors. Moreover, in view of the associated manufacturing costs, application of light sources on large surface areas is trending towards organic light emitting diodes replacing conventional light emitting diodes. In comparison to conventional light emitting diodes in the field of light emitting diode displays, organic light emitting diodes have simpler manufacturing processes which lead to a reduction in costs. Since organic light emitting diodes are also self-luminous, additional backlight modules in light emitting diode displays to act as the display light source are unnecessary. Without the need for backlight modules, organic light emitting diode displays utilized in electronic devices can better meet product specifications for fancier, lighter, shorter, smaller, and energy efficient products. As a result, organic light emitting diodes are especially useful in popular portable electronic devices, and can potentially replace liquid crystal displays to become the de facto standard for flat panel displays.

However, due to the properties of organic light emitting diodes, the oxygen and moisture in the air may greatly affect the lifespan of organic light emitting diodes. Therefore, there is a need to first package the organic light emitting diodes before usage. Traditionally, glass is used to cover the organic light emitting diode. However, in regards to larger surface areas of area light sources, displays with larger display dimensions, or where products with specification limitations on weight and thickness are concerned, glass is not a viable material to use as a cover for organic light emitting diodes.

### SUMMARY OF THE INVENTION

It is an object of the present invention to provide an organic light emitting diode packaging structure. In comparison to the prior art, the organic light emitting diode packaging structure of the present invention possesses the characteristic of being able to barricade air out of the structure while also having advantages in smaller thickness, lighter weight, and lower cost.

It is another object of the present invention to provide a manufacturing method of the organic light emitting diode packaging structure. Also in comparison to the prior arts, the manufacturing method of the present invention can also prevent the organic light emitting diode and the packaging structure from damage during the manufacturing process.

The organic light emitting diode packaging structure of the present invention includes a substrate, an organic light emitting diode, a film, and a metal layer. The organic light emitting diode is disposed on the substrate. The film has a surface facing the substrate surface. The surface has a recess. The metal layer is disposed on the film surface and forms an accommodating space for accommodating the organic light emitting diode in the recess. The utilization of metal layer to package the organic light emitting diode provides advantageous characteristics such as smaller thickness and lighter weight. These advantages are suitable for large organic light emitting diode products or for portable electronic devices.

The manufacturing method of the present invention includes the following steps: disposing the organic light emitting diode on the substrate; providing a film, wherein the film has a recess formed on a surface thereof; disposing the metal layer along the surface of the film to form an accommodating space in the recess; disposing the film on the substrate so that the metal layer is attached to the substrate, and the organic light emitting diode is accommodated in the accommodating space. The present invention utilizes the metal layer to package the organic light emitting diode while utilizing the recessed film design to prevent both the organic light emitting diode and the covering metal layer from damage during the course of pressing the film onto the substrate.

### BRIEF DESCRIPTION OF THE DRAWINGS

FIG. 1A is the first embodiment of the organic light emitting diode packaging structure;

FIG. 1B is a perspective view diagram of FIG. 1A;

FIG. 2 is a schematic diagram of the second embodiment of the organic light emitting diode packaging structure;

FIG. 3A is a schematic diagram of the organic light emitting diode packaging structure with dry unit;

FIG. 3B is another schematic diagram of the organic light emitting diode packaging structure with dry unit;

FIG. 4 is a schematic diagram of the organic light emitting diode packaging structure with water-resistant protective layer;

FIG. 5 is a schematic diagram of the organic light emitting diode packaging structure with soft isolating layer;

FIG. 6A is a schematic diagram of the third embodiment of the organic light emitting diode packaging structure;

FIG. 6B is a schematic diagram depicted in FIG. 6A with dry unit;

FIG. 7A is a schematic diagram of the organic light emitting diode packaging structure with filler layer;

FIG. 7B is another schematic diagram of the organic light emitting diode packaging structure with filler layer;

FIG. 8A is a flowchart diagram of the manufacturing method of the organic light emitting diode packaging structure;

FIG. 8B another flowchart diagram depicted in FIG. 8A of the manufacturing method of the organic light emitting diode packaging structure with the step of forming the recess;

FIG. 9 is a flowchart diagram of the manufacturing method of the second embodiment of the organic light emitting diode packaging structure;

FIG. 10 is a flowchart diagram of the manufacturing method of the third embodiment of the organic light emitting diode packaging structure;

FIG. 11 is a flowchart diagram of the manufacturing method of the fourth embodiment of the organic light emitting diode packaging structure;

FIG. 12 is a flowchart diagram of the manufacturing method of the fifth embodiment of the organic light emitting diode packaging structure; and

FIG. 13 is a flowchart diagram of the manufacturing method of the sixth embodiment of the organic light emitting diode packaging structure.

### DETAILED DESCRIPTION OF THE PREFERRED EMBODIMENT

The present invention provides an organic light emitting diode packaging structure and a manufacturing method thereof. In the preferred embodiment, the organic light emitting diode packing structure is utilized in lighting devices or electronic display devices. The manufacturing method of the present invention may be applied to roll-to-roll or roll-to-sheet manufacturing processes. However, in other embodiments, the present invention may be utilized in other alternative electronic devices. The manufacturing method of the present invention may also be applied to the manufacturing process of other alternative devices.

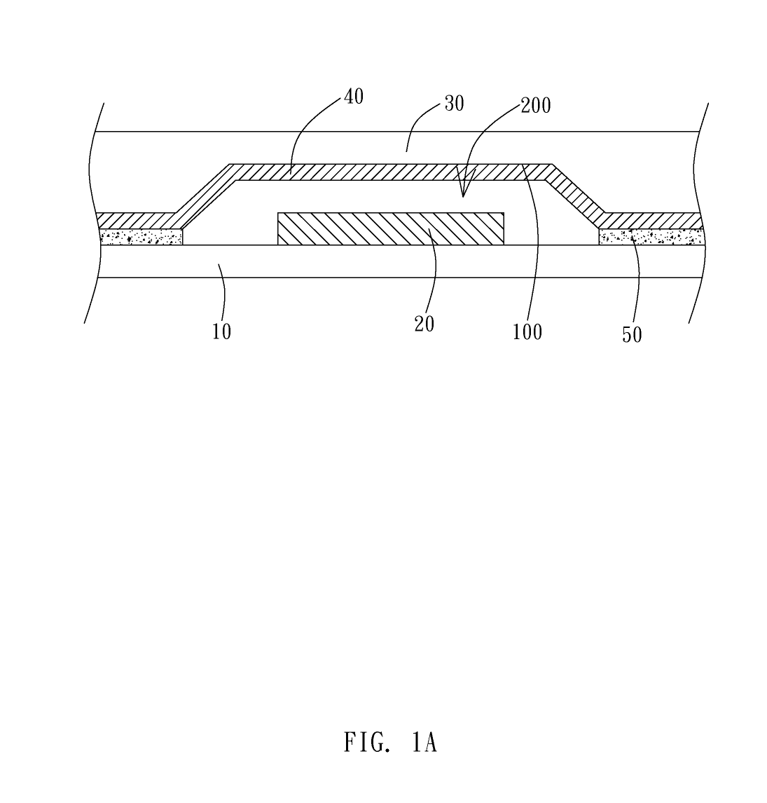

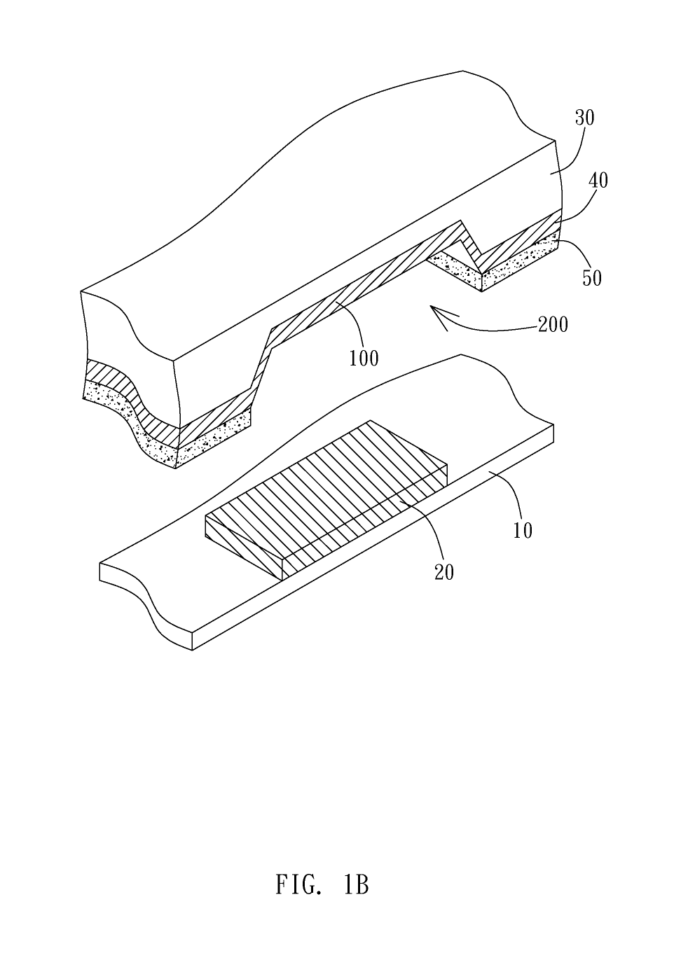

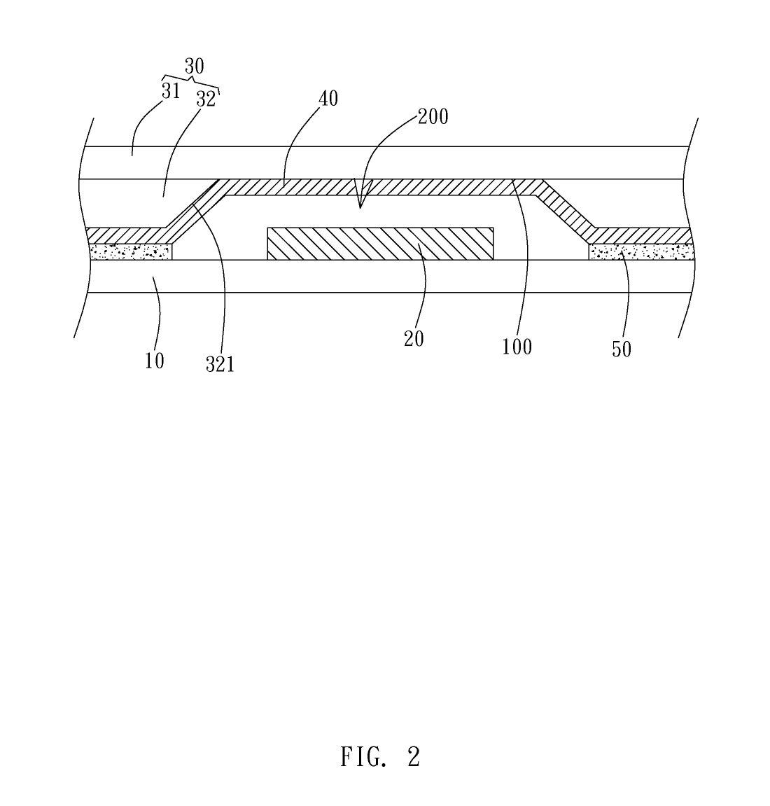

FIG. 1A illustrates the first embodiment of the organic light emitting diode packaging structure of the present invention. FIG. 1B is a perspective view of the organic light emitting diode packaging structure of FIG. 1A. As shown in FIGS. 1A and 1B, the organic light emitting diode packaging structure includes a substrate 10, an organic light emitting diode 20, a film 30, and a metal layer 40. The organic light emitting diode 20 is disposed on the substrate 10. The film 30 has a recess 100 on its surface that faces the substrate 10. In the preferred embodiment, the film 30 may be a flexible printed circuit (FPC) board, a polyethylene terephthalate (PET) film, a poly-imides (PI) film, or a polyethylene naphthalate (PEN) film. However, in other embodiments, the film 30 may be a thin film or board of other soft materials. In the present embodiment, the recess 100 is formed by indenting a thin soft film or slim board, wherein a non-splicing manufacturing method is utilized to create the film 30. However, in other embodiments, the recess 100 can be formed by different methods according to requirements. FIG. 2 is the second embodiment of the organic light emitting diode packaging structure of the present invention. As shown in FIG. 2, the film 30 includes a first layer 31 and a second layer 32 adhered to each other. The second layer 32 has a through hole 321, wherein the through hole 321 and the first layer 31 together form the recess 100 as the first layer 31 and the second layer 32 are adhered together. The first layer 31 is preferably adhered to the second layer 32 by utilizing a roller.

The metal layer 40 is disposed on the film 30, so that the metal layer 40 forms an accommodating space 200 within the recess 100 to accommodate the light emitting diode 20. Besides the portion of the metal layer 40 provided for forming the accommodating space 200, the other portions of the metal layer 40 is glued onto the substrate 10 through an adhesive layer 50. The size and shape of the accommodating space 200 may be adjusted based on the organic light emitting diode 20 to be accommodated therein. In the present embodiment, the material of the metal layer 40 is aluminum, while the material of the adhesive layer 50 is epoxy or UV glue. However, in other embodiments, the material of the metal layer 40 may be other metals while the material of the adhesive layer 50 may be pressure sensitive adhesives, photo sensitive adhesive, or any suitable adhesive. The present embodiment utilizes the metal layer 40 to package the organic light emitting diode 20 to prevent the oxygen and moisture in the air from interacting with the organic light emitting diode 20. In comparison to the prior art, the present invention has advantages in smaller thickness, lighter weight, and lower costs. Therefore, the present invention is better suited for large organic light emitting diode products or portable electronic devices.

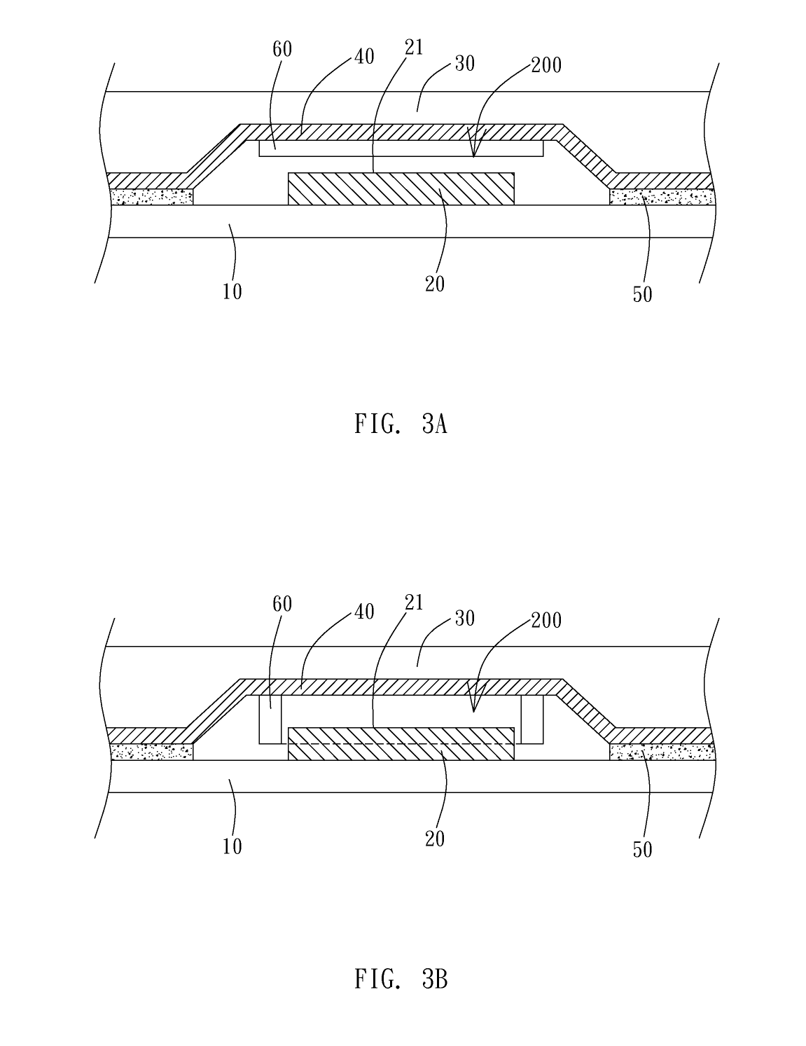

To maintain the destitution of moisture, a dryer may be disposed within the accommodating space 200. FIG. 3A is a schematic diagram illustrating an embodiment of the organic light emitting diode packaging structure with a drying unit. The drying unit is preferably a dryer that is disposed within the accommodating space 200 on the metal layer 40, or disposed in another location within the accommodating space 200. As shown in FIG. 3A, the organic light emitting diode 20 has a top surface 21 opposite to the substrate 10, and a dry unit 60 is disposed between the metal layer 40 and the top surface 21. However, in other embodiments, the dry unit 60 may be disposed to any suitable location as required. FIG. 3B is a schematic diagram of another embodiment of the organic light emitting diode packaging structure with drying unit. FIG. 3B illustrates a ring shaped drying unit 60 on the metal layer 40 extending towards the substrate 10 and at least partially encircling the outer side of the organic light emitting diode 20.

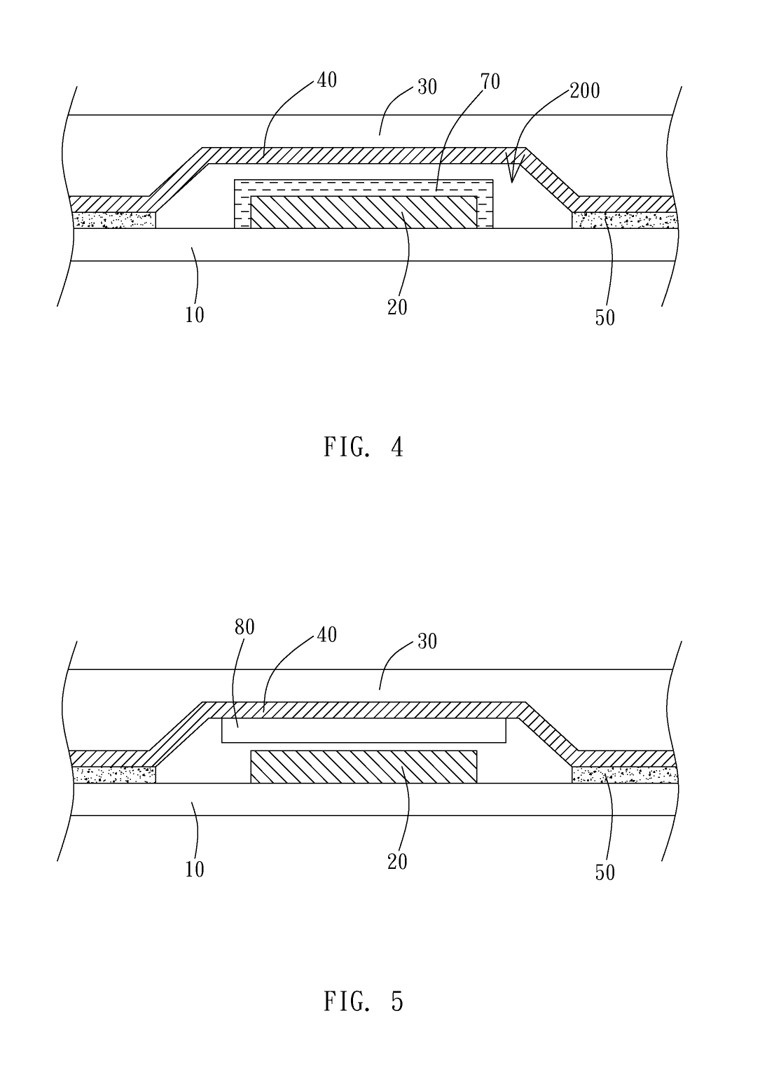

Besides utilizing a dryer, a water-resistant protective layer may be disposed on the surface of the organic light emitting diode 20 to prevent the organic light emitting diode 20 from moisture in the accommodating space. FIG. 4 is a schematic diagram of the present invention with a water-resistant protective layer 70 implemented. As shown in FIG. 4, the water-resistant protective layer 70 is disposed between the organic light emitting diode 20 and the metal layer 40 within the accommodating space 200 and completely covers the organic light emitting diode 20. However, in other embodiments, the water-resistant protective layer 70 may cover only the cathode of the organic light emitting diode 20 or may cover any portion of the organic light emitting diode most easily affected by moisture.

Since the organic light emitting diode 20 and the metal layer 40 within the accommodating space 200 are separated only by a small gap, to prevent the organic light emitting diode 20 from surface contamination or uneven contact of the metal layer 40, a soft isolating layer may be disposed between the organic light emitting diode 20 and the metal layer 40. FIG. 5 is a schematic diagram illustrating an embodiment of the organic light emitting diode packaging structure with a soft isolating layer implemented. As shown in FIG. 5, a soft isolating layer 80 partially covers the metal layer 40 within the accommodating space 200 to prevent the organic light emitting diode 20 from contacting the metal layer 40. The preferable material for the soft isolating layer 80 includes soft materials such as silicone to prevent damage to both the organic light emitting diode 20 and the metal layer 40 when contacting the soft isolating layer 80.

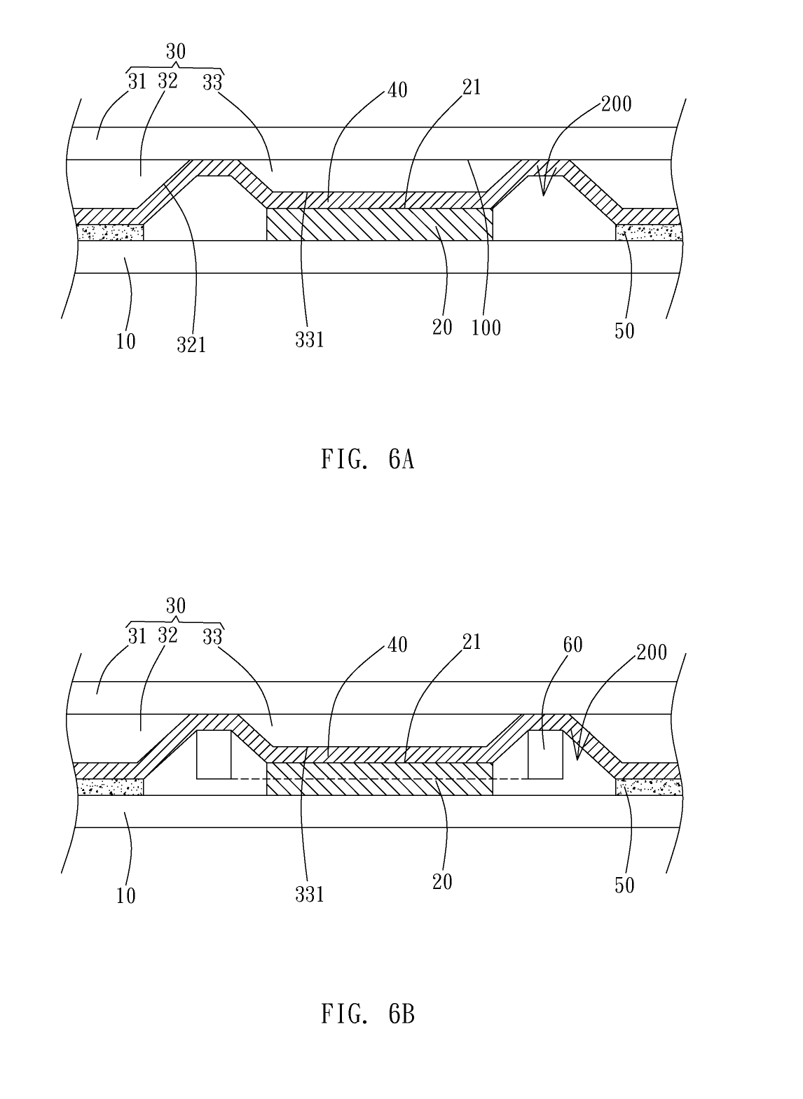

In the above embodiments, as the organic light emitting diode 20 is disposed in the accommodating space 200, a gap exists between the organic light emitting diode 20 and the metal layer 40. FIG. 6A is a schematic diagram of the third embodiment of the organic light emitting diode packaging structure. As shown in FIG. 6A, the film 30 includes a first layer 31, a second layer 32, and a third layer 33. The second layer 32 has a through hole 321 and adheres to the first layer 31 so that the through hole 321 together with the first layer 31 form the recess 100. The third layer 33 is disposed within the recess 100 and adheres to the first layer 31 to form a protruding portion 331 within the recess 100. The preferred adherence method for the adhesion between the first layer 31 and the second layer 32, and between the first layer 31 and the third layer 33, entails utilizing a roller press. The protruding portion 331 extends toward the top surface 21 of the organic light emitting diode 20, allowing the metal layer 40 on the protruding portion 331 to contact the top surface 21. The direct contact between the metal layer 40 on the protruding portion 331 and the top surface 21 can prevent the organic light emitting diode 20 and the metal layer 40 from damage induced by relative movement of the substrate 10 and the film 30. In addition, the drying unit 60 may also be implemented in the present embodiment. FIG. 6B is a schematic diagram of FIG. 6A with the drying unit implemented. As shown in FIG. 6B, the metal layer 40 on the protruding portion 331 contacts the top surface 21, while the drying unit 60 is disposed within the space surrounding the protruding portion 331 including the metal layer 40 thereon in the accommodating space 200.

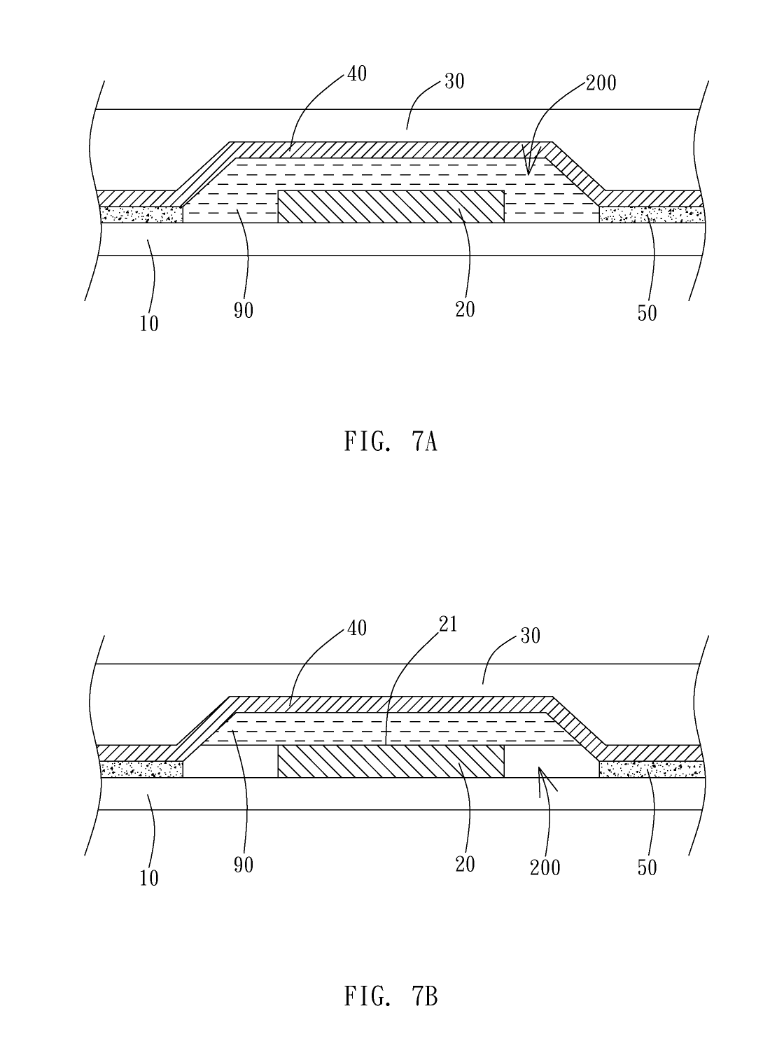

In addition, a filler layer may be disposed within the accommodating space 200 to fill the gap between the organic light emitting diode 20 and the metal layer 40. FIG. 7A is a schematic diagram of an embodiment of the organic light emitting diode packaging structure with the filler layer implemented. As shown in FIG. 7A, a filler layer 90 fills the accommodating space 200 between the organic light emitting diode 20 and the metal layer 40. The filler layer 90 is preferably made of a thermal conductive material to dissipate the heat generated by the organic light emitting diode 20. In addition, other related materials such as epoxy resins or liquid filler materials may be utilized as appropriate. In other embodiments, the filler layer 90 need not completely fill the accommodating space 200. For instance, the filler layer 90 may cover only a portion of the organic light emitting diode 20. FIG. 7B is a schematic diagram of another embodiment of the organic light emitting diode packaging structure with the filler layer implemented. As shown in FIG. 7B, the filler layer 90 is disposed within the space between the surface 21 and the metal layer 40, wherein the filler layer 90 is preferably a thermal conductive material.

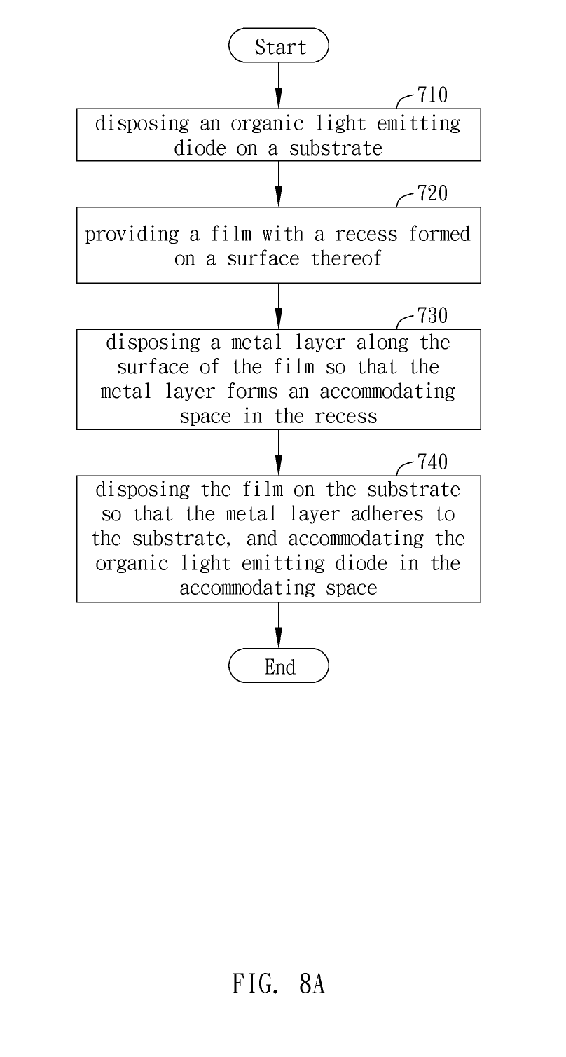

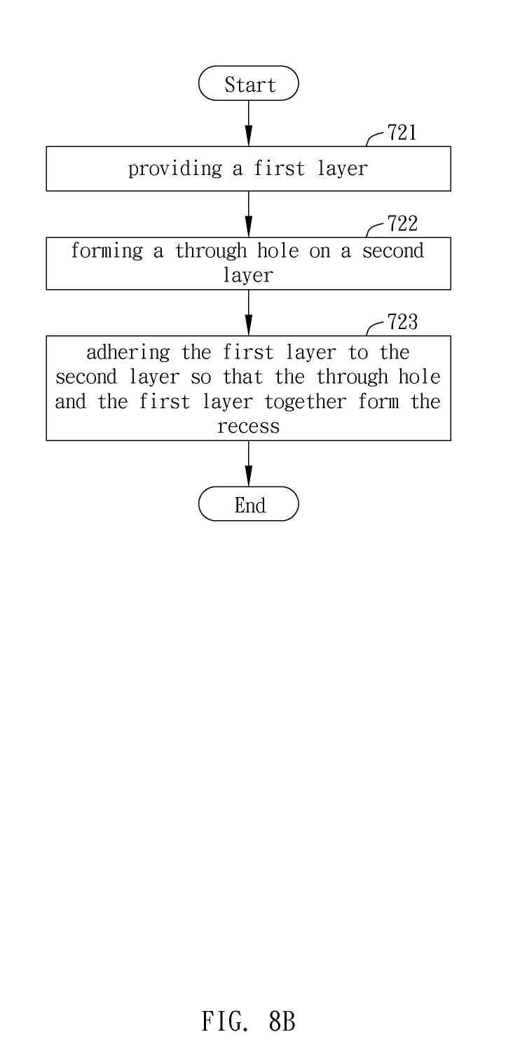

FIG. 8A is a flowchart of the manufacturing method of the present invention. As shown in FIG. 8A, step 710 includes disposing an organic light emitting diode on a substrate. Step 720 includes providing a film with a recess formed on a surface thereof. In the preferred embodiment, the film may be a flexible printed circuit (FPC) board, a polyethylene terephthalate (PET) film, a poly-imides (PI) film, or a polyethylene naphthalate (PEN) film. However, in other embodiments, other soft thin films or slim boards may be utilized. In the present embodiment, the recess is formed on the soft thin film or slim board by indenting the soft thin film or slim board, instead of a non-splicing method. However, in other embodiments, multiple film layers may be adhered together to form the recess. FIG. 8B shows another embodiment of FIG. 8A in the step of forming the recess. As shown in FIG. 8B, step 721 includes providing a first layer. Step 722 includes forming a through hole on a second layer. Step 723 includes adhering the first layer to the second layer, so that the through hole and the first layer together form the recess. In the preferred embodiment, the second layer adheres to the first layer by utilizing a roller to press the second layer onto the first layer.

As shown in FIG. 8A, step 730 includes disposing a metal layer along the surface of the film so that the metal layer forms an accommodating space in the recess. That is, the metal is preferably disposed on the film conformally. In the preferred embodiment, the metal layer is disposed on the surface of the film by utilizing a roller. In the present implementation, the material of the metal layer is aluminum. However, in other embodiments, other metals may be utilized for the metal layer. Step 740 includes disposing the film on the substrate so that the metal layer adheres to the substrate, and accommodating the organic light emitting diode in the accommodating space. In the preferred embodiment, a roller is used to press the film onto the substrate. In the present embodiment, an adhesive layer based on an epoxy resin or Ultra-violet curing glue is used to glue together the metal layer and the substrate. However, in other embodiments, the adhesive layer can be based on other materials such as pressure sensitive adhesives, photo sensitive adhesives, or any suitable adhesive materials. The present invention uses the metal layer to package the organic light emitting diode while utilizing the recessed film design to prevent the organic light emitting diode and the covering metal layer from damage in the process of pressing the film onto the substrate.

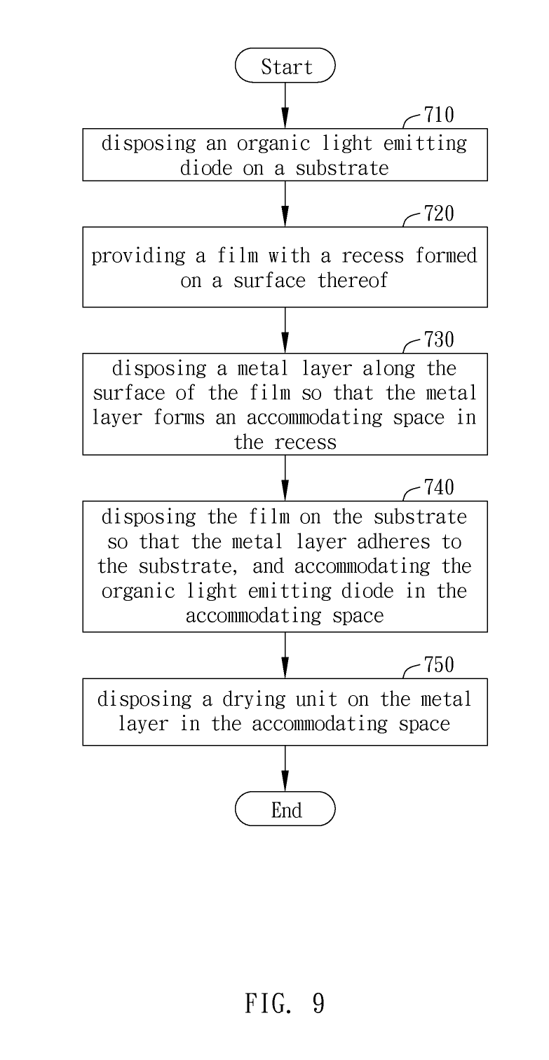

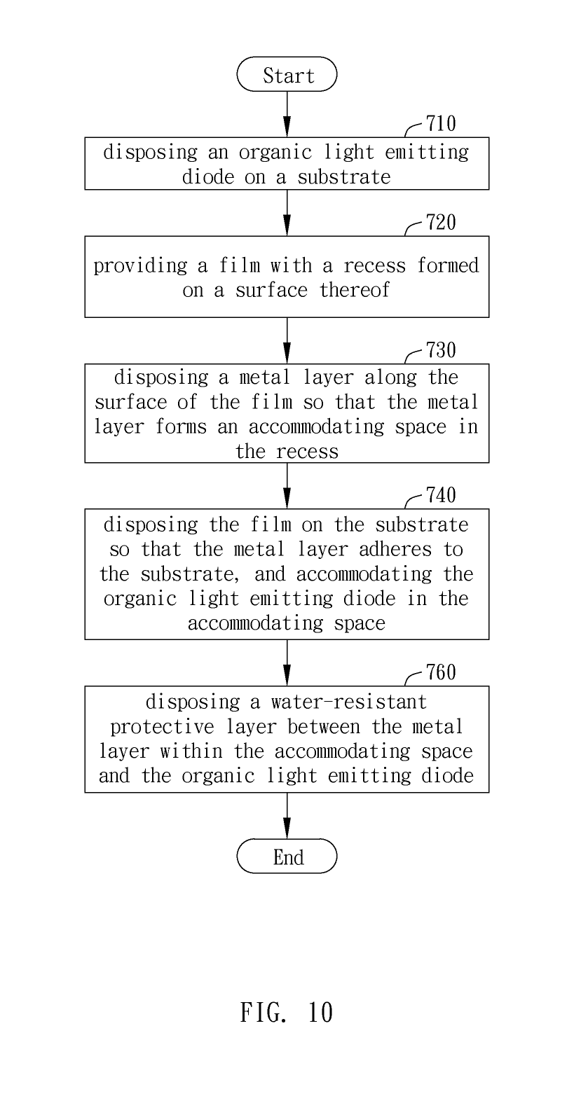

To maintain the destitution of moisture, a dryer may be disposed within the accommodating space. FIG. 9 is a flowchart illustrating the manufacturing method of the second embodiment of the organic light emitting diode packaging structure. As shown in FIG. 9, besides the mentioned steps 710, 720, 730, and 740, the manufacturing method further includes step 750 of disposing a drying unit on the metal layer in the accommodating space, wherein the drying unit is preferably a dryer. The drying unit may be disposed on the metal layer in the accommodating space, opposite to the top surface of the organic light emitting diode (as shown in FIG. 3A), or may be disposed on any suitable location as required. For instance, the drying unit may be in a ring shape, disposed on the metal layer while extending towards and encircling at least a portion of the organic light emitting diode (shown in FIG. 3B).

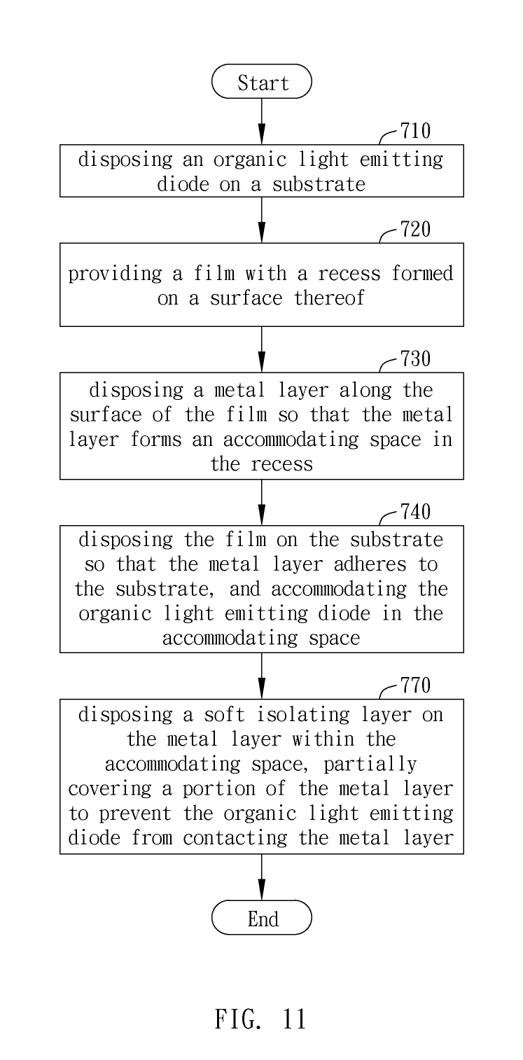

Besides utilizing a dryer, a water-resistant protective layer may be disposed on the surface of the organic light emitting diode to prevent the organic light emitting diode form moisture. FIG. 10 is a flowchart illustrating the manufacturing method of the third embodiment of the organic light emitting diode packaging structure. Besides the mentioned steps 710, 720, 730, and 740, the manufacturing method further includes step 760 of disposing a water-resistant protective layer between the metal layer within the accommodating space and the organic light emitting diode. As well, the water-resistant protective layer completely covers the organic light emitting diode. However, in other embodiments, the water-resistant protective layer may selectively cover only portions of the organic light emitting diode that are more susceptible to moisture.

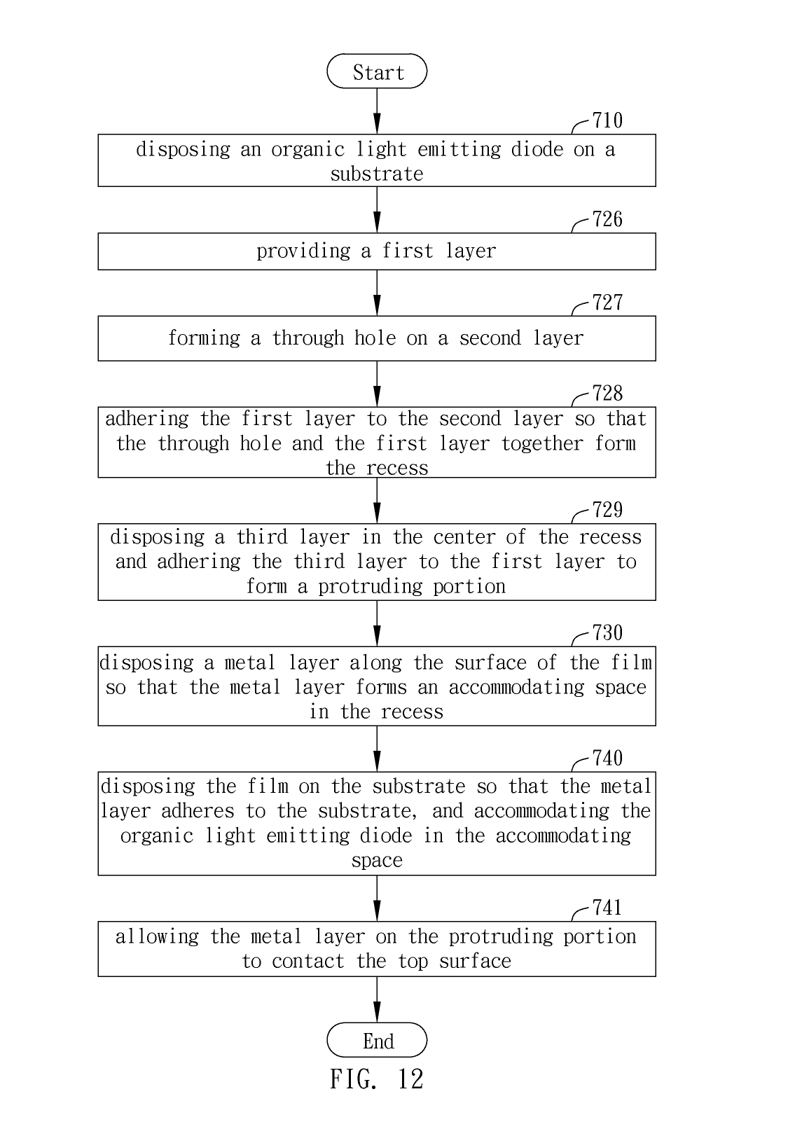

Since the organic light emitting diode and the metal layer within the accommodating space are separated only by a small gap, to prevent the organic light emitting diode from surface contamination or uneven contact of and the metal layer, a soft isolating layer may be disposed between the organic light emitting diode and the metal layer. FIG. 11 is a flowchart of the fourth embodiment of the organic light emitting diode packaging structure. Besides the mentioned steps 710, 720, 730, and 740, the manufacturing method further includes step 770 of disposing a soft isolating layer on the metal layer within the accommodating space, partially covering a portion of the metal layer to prevent the organic light emitting diode from contacting the metal layer (as shown in FIG. 5). The preferred material for the soft isolating layer includes soft materials such as silicone to prevent damage to both the organic light emitting diode and the metal layer.

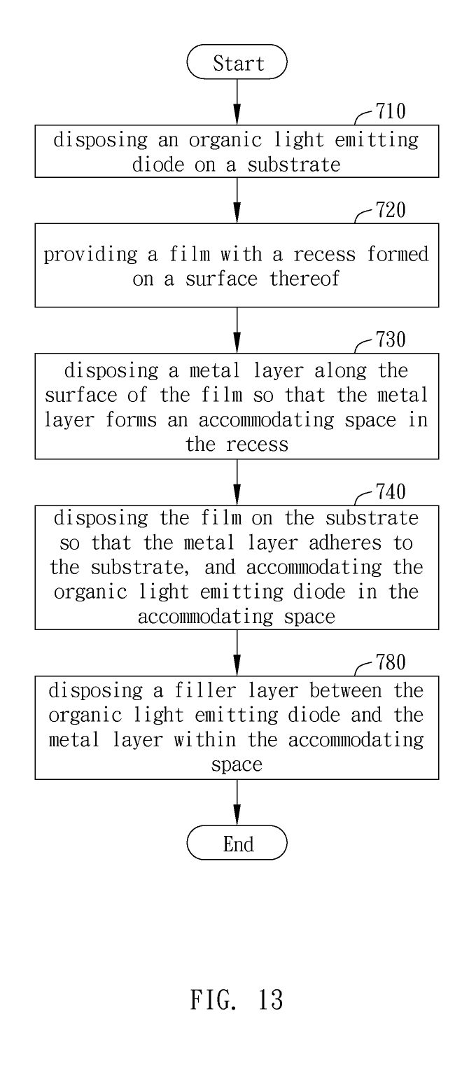

In the above embodiments, as the organic light emitting diode is disposed in the accommodating space, a gap exists between the organic light emitting diode and the metal layer. FIG. 12 is a flowchart illustrating the manufacturing method of the fifth embodiment of the organic light emitting packaging structure. Besides the mentioned steps 710, 730, and 740, the manufacturing method further includes step 726, 727, 728, 729, and 741. Step 726 includes providing a first layer. Step 727 includes forming a through hole on a second layer. Step 728 includes adhering the first layer to the second layer, so that the through hole and the first layer together form the recess. Step 729 includes disposing a third layer in the center of the recess and adhering the third layer to the first layer to form a protruding portion. The protruding portion extends towards the top surface of the organic light emitting diode. Step 741 includes allowing the metal layer on the protruding portion to contact the top surface. The direct contact between the metal layer and the top surface prevents both the organic light emitting diode and the metal layer from damage induced by the relative movement of the substrate and the film. In addition, the drying unit may be disposed on the metal layer in the recesses surrounding the organic light emitting diode (shown in FIG. 6B). The preferred method for the adhesion between the first layer and the second layer and between the first layer and the third layer entails utilizing a roller press. The second layer is pressed onto the first layer with the roller. The third layer is pressed onto the first layer with the roller.

In addition, a filler layer may be disposed within the accommodating space to fill the gap between the organic light emitting diode and the metal layer. FIG. 13 is a flowchart illustrating the manufacturing method of the sixth embodiment of the organic light emitting diode packaging structure. Besides the mentioned steps 710, 720, 730, and 740, the manufacturing method further includes step 780. Step 780 includes disposing a filler layer between the organic light emitting diode and the metal layer within the accommodating space. The filler layer may completely fill the accommodating space between the organic light emitting diode and the metal layer (as shown in FIG. 7A). The preferred material for the filler layer is a thermal conductive material to dissipate the heat generated by the organic light emitting diode. However, other related materials such as epoxy resins or liquid filler materials may also be utilized as appropriate. In other embodiments, the filler need not completely fill the accommodating space. For instance, the filler may cover only a portion of the organic light emitting diode. The filler layer is disposed within the space between the top surface and the metal layer (shown in FIG. 7B), wherein the filler layer is preferably a thermal conductive material.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. A manufacturing method of an organic light emitting diode (OLED) packaging structure, comprising:
disposing at least one organic light emitting diode on a substrate;
providing a film with at least one recess formed on a surface thereof;
disposing a metal layer along the surface of the film so that the metal layer forms an accommodating space in the recess; and
disposing the film on the substrate, wherein the metal layer is attached to the substrate and the accommodating space accommodates the at least one organic light emitting diode.

2. The manufacturing method of claim 1, wherein the step of disposing the metal layer comprises using a roller to adhere the metal layer to the surface of the film.

3. The manufacturing method of claim 2, the step of disposing the film comprises using the roller to press the film onto the substrate.

4. The manufacturing method of claim 1, wherein the step of forming the film comprises:
providing a first layer;
forming at least one through hole in a second layer; and
adhering the first layer to the second layer so that the through hole together with the first layer forms the recess.

5. The manufacturing method of claim 4, wherein the step of adhering the first layer and the second layer comprises using a roller to press the second layer onto the first layer.

6. The manufacturing method of claim 1, further comprising disposing at least a drying unit on the metal layer within the accommodating space.

7. The manufacturing method of claim 1, further comprising disposing a water-resistant protective layer between the organic light emitting diode and the metal layer in the accommodating space, allowing the water-resistant protective layer to cover at least a portion of the organic light emitting diode.

8. The manufacturing method of claim 1, further comprising forming at least one protruding portion in the recess, wherein the organic light emitting diode has a top surface opposite to the substrate, the protrusion extends toward the top surface, and the step of disposing the film further comprises making the metal layer on the protruding portion come in contact with the top surface.

9. The manufacturing method of claim 1, further comprising disposing a soft isolating layer on the metal layer within the accommodating space, to cover at least a portion of the metal layer and prevent the organic light emitting diode from contacting the metal layer.

10. The manufacturing method of claim 1, further comprising disposing a filler layer between the organic light emitting diode and the metal layer within the accommodating space.

11. An organic light emitting diode (OLED) packaging structure, comprising:
a substrate;
at least one organic light emitting diode disposed on the substrate;
a film having a surface facing the substrate, the surface having at least one recess; and
a metal layer disposed on the surface so that the metal layer forms an accommodating space in the recess to accommodate the OLED.

12. The organic light emitting diode packaging structure of claim 11, wherein the film comprises a first layer and a second layer adhered to each other, the second layer has at least a through hole, and the through hole and the first layer together form the recess.

13. The organic light emitting diode packaging structure of claim 11, further comprising at least a drying unit disposed on the metal layer in the accommodating space.

14. The organic light emitting diode packaging structure of claim 13, wherein the drying unit extends towards the substrate and surrounds at least a portion of the organic light emitting diode.

15. The organic light emitting diode packaging structure of claim 11, further comprising disposing a water-resistant protective layer between the organic light emitting diode and the metal layer in the accommodating space, covering at least a portion of the organic light emitting diode.

16. The organic light emitting diode packaging structure of claim 11, further comprising forming at least one protruding portion in the recess, wherein the organic light emitting diode has a top surface opposite to the substrate, the protruding portion extends towards the top surface to allow the metal layer on the protruding portion to come in contact with the top surface.

17. The organic light emitting diode packaging structure of claim 11, further comprising a soft isolating layer covering at least a portion of the metal layer in the accommodating space to prevent the organic light emitting diode from contacting the metal layer.

18. The organic light emitting diode packaging structure of claim 11, further comprising a filler layer disposed between the organic light emitting diode and the metal layer in the accommodating space.

19. The organic light emitting diode packaging structure of claim 18, wherein the filler layer at least partially covers the organic light emitting diode, and the filler layer comprises a thermal conductive material.

20. The organic light emitting diode packaging structure of claim 11, wherein the film comprises a flexible printed circuit (FPC) board, a polyethylene terephthalate (PET) film, a poly-imides (PI) film, or a polyethylene naphthalate (PEN) film.
